(19) United States
(12) Patent Application Publication
(10) Pub. No.: US 2009/0291373 A1
(43) Pub. Date: Nov. 26, 2009

(54) Green Photoresist and Color Filter Substrate using the same

(76) Inventors: Chien-Kai CHEN, Hsinchu City (TW); Ya-Ling Hsu, Hsinchu City (TW); Chun-Liang Lin, Hsinchu City (TW); Chen-Hsien Liao, Hsinchu City (TW)

Correspondence Address: HDLS Patent & Trademark Services, P.O. BOX 220746, CHANTILLY, VA, 20153-0746, US

(21) Appl. No.: 12/210,222

(22) Filed: Sep. 15, 2008

(30) Foreign Application Priority Data
May 23, 2008 (TW) 097119133

(51) Int. Cl. G03F 1/00; G03F 7/004

(52) U.S. Cl. 430/7; 430/281.1; 430/270.1

(57) ABSTRACT

In a green photoresist for a color filter substrate, GY×Gy is greater than 33 when the green photoresist is tested by a standard C light source and Gy is greater than or equal to 0.6. A light beam from the standard C light source after passing through the green photoresist corresponds to a y coordinate in a CIE 1931 chromaticity diagram and Gy represents the y coordinate. GY represents light transmittance of the green photoresist for the light beam from the standard C light source. The green photoresist improves the light transmittance. Further, a color filter substrate using the green photoresist is provided.

### BACKGROUND

1. Field of the Invention

The present invention relates to a color filter substrate, and particularly to a green photoresist for the color filter substrate and a color filter substrate using the same.

2. Description of the Prior Art

With continuous progress, flat displays are widely used due to their attractive characteristics such as light weight, compact volume and low power consumption. Familiar flat displays includes liquid crystal displays (LCDs), plasma display panels (PDPs), organic light emitting diode displays, (OLED displays), and electrophoretic displays (EPDs). Generally, LCDs are the most popular.

Typically, an LCD includes an LCD panel and a backlight module for providing a display light to the LCD panel. Generally, the LCD panel employs a color filter substrate to filter the display light (i.e. a white light) so as to achieve a colorful display. However, because of the filter characteristic of color filter substrate, brightness of the display light provided by the backlight module is greatly reduced after the display light passing through the color filter substrate. In addition, nowadays, LCDs tend to obtain high color saturation. In order to achieve high color saturation, usually, thickness of the color photoresists in color filter substrate is increased, but light transmittance of the color photoresists for the display light is consequently reduced.

### BRIEF SUMMARY

The present invention provides a green photoresist having improved light transmittance.

The present invention also provides a color filter substrate capable of improving a light usage efficiency of a liquid crystal display.

A green photoresist for a color filter substrate is provided. GY×Gy is greater than 33 when the green photoresist is tested by a standard C light source and Gy is greater than or equal to 0.6. A light beam from the standard C light source after passing through the green photoresist corresponds to a y coordinate in a CIE 1931 chromaticity diagram and Gy represents the y coordinate. GY represents light transmittance of the green photoresist for the light beam from the standard C light source.

In one embodiment of the present invention, the green photoresist includes at least one kind of green pigments.

In another embodiment of the present invention, the green pigment is composed of halogenated metallophthalocyanine

In another embodiment of the present invention, the green pigment is composed of brominated zinc phthalocyanine

In another embodiment of the present invention, the green photoresist further includes at least one kind of yellow pigments.

In one embodiment of the present invention, the yellow pigment includes color index (C.I.) Pigment Yellow 150 and/or C.I. Pigment Yellow 139.

In one embodiment of the present invention, a transmission spectrum of the green photoresist has a relative maximum valve between 520 nanometers (nm) and 580 nm.

The present invention also provides a color filter substrate. The color filter substrate includes a substrate, a plurality of red photoresists, a plurality of the abovementioned green photoresists and a plurality of red photoresists, wherein the red photoresists, the blue photoresists and the green photoresists are disposed on the substrate.

Because GY×Gy is greater than 33 when the green photoresist is tested by the standard C light source and Gy is greater than or equal to 0.6, the light transmittance of the green photoresist is consequently increased. Accordingly, the color filter substrate of the present invention can achieve high color saturation without greatly decreasing light transmittance. Thus, the display apparatus employs the color filter substrate can achieve high light usage efficiency.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a cross sectional view showing a color filter substrate in accordance with an embodiment of the present invention.

FIG. 2 is a transmission spectrum that shows light transmittance of the green photoresist employed in the color filter substrate of FIG. 1 and two conventional green photoresists, and FIG. 2 further shows a color matching function.

### DETAILED DESCRIPTION

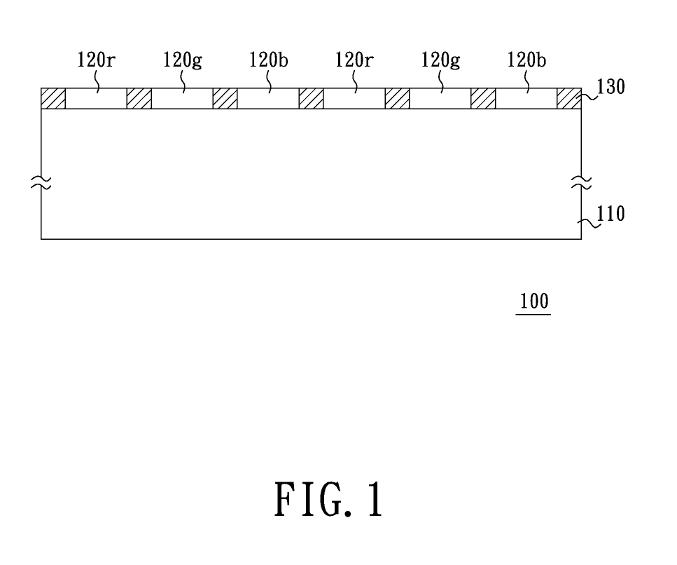

FIG. 1 is a cross sectional view showing a color filter substrate in accordance with an embodiment of the present invention. The color filter substrate 100 of the present embodiment includes a substrate 110, a plurality of red photoresists 120r, a plurality of green photoresists 120g, and a plurality of blue photoresists 120b, wherein the red photoresists 120r, the green photoresists 120g and the blue photoresists 120b are disposed on the substrate 110. The color filter substrate 100 further includes a black matrix 130 for shielding light. The black matrix 130 is also disposed on the substrate 110, and the red photoresists 120r, the green photoresists 120g and the blue photoresists 120b are distributed in areas surrounded by the black matrix 130.

To improve light transmittance of the green photoresists 120g in the color filter substrate 100, in the present embodiment, composition and proportion of pigments in the green photoresists 120g are formulated to achieve that GY×Gy is greater than 33 when the green photoresists 120g are tested by a standard C light source and Gy is greater than or equal to 0.6. A light beam from the standard C light source after passing through one of the green photoresists 120g corresponds to a y coordinate in a CIE 1931 chromaticity diagram and Gy represents the y coordinate. GY represents the light transmittance of the green photoresists 120g for the light beam from the standard C light source. In addition, the color temperature of the standard C light source is 6774K.

Specifically, to meet above requirements, in the present embodiment, each of the green photoresists 120g includes at least one kind of green pigments. The green pigment is, for example, composed of halogenated metallophthalocyanine such as brominated zinc phthalocyanine. In addition, each of the green photoresists 120g can further includes at least one kind of yellow pigments. The yellow pigment can be C.I. Pigment Yellow 150, C.I. Pigment Yellow 139 and combination thereof.

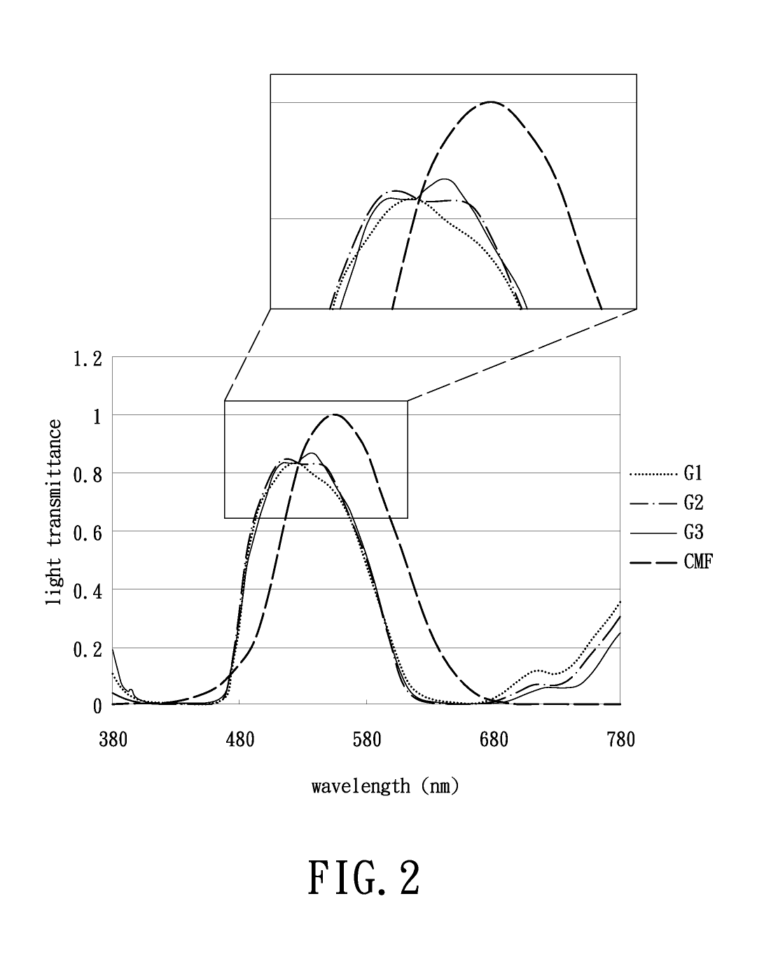

FIG. 2 is a transmission spectrum that shows light transmittance of the green photoresist employed in the color filter substrate of FIG. 1 and two conventional green photoresists, and FIG. 2 further shows a color matching function. In addition, curve G2 represents a transmission spectrum of a first conventional green photoresist, curve G3 represents a transmission spectrum of a second conventional green photoresist, curve G3 represents a transmission spectrum of the green photoresists 120g of the present embodiment, and curve CMF represents the color matching function. As shown in FIG. 2, in the present embodiment, the purpose of limiting that GY×Gy is greater than 33 when the green photoresists 120g are tested by the standard C light source and Gy is greater than or equal to 0.6 is to improve the light transmittance of the green photoresists 120g in a certain wavelength range (between 520 nm and 560 nm) of the transmission spectrum. The certain wavelength range is an intersection area of the transmission spectrum of the green photoresists 120g and the color matching function. Accordingly, the transmission spectrum of the green photoresists 120g (i.e. curve G3) has a relative maximum valve between 520 nm and 580 nm.

As shown in FIG. 2, the relative maximum values of the transmission spectrums of the two conventional green photoresists (referring to curves G1 and G2) is out of the color matching function (referring to curve CMF). In contrast, the relative maximum value of the transmission spectrum of the green photoresists 120g (referring to curve G3) is in the range of the color matching function (referring to curve CMF). Accordingly, the color filter substrate 100 can improve color saturation of the display apparatus without greatly decreasing the light transmittance. Thus, the display apparatus employs the color filter substrate 100 can achieve high light usage efficiency.

In order to further explain the difference between the green photoresists 120g and the two conventional photoresists, the test results will be discussed. However, it is to be understood that the test results are used to illustrate the green photoresists 120g rather than limit scope of the green photoresists 120g.

TABLE 1

| | x | y | Light transmittance (%) |
|---|---|---|---|
| The first conventional | 0.288 | 0.589 | 55.20 |
| photoresist | | | |
| The second | 0.283 | 0.589 | 56.88 |
| conventional | | | |
| photoresist | | | |
| The green photoresist | 0.289 | 0.589 | 57.63 |
| 120 g of the present | | | |
| embodiment | | | |

TABLE 2

| | x | y | Light transmittance (%) |
|---|---|---|---|
| The first conventional | 0.281 | 0.599 | 52.07 |
| green photoresist | | | |
| The second | 0.278 | 0.599 | 54.22 |
| conventional green | | | |
| photoresist | | | |
| The green photoresist | 0.282 | 0.599 | 56.36 |
| 120 g of the present | | | |
| embodiment | | | |

The light beam from the standard C light source after passing through one of the two conventional green photoresists and the green photoresist 120g corresponds to a x coordinate and a y coordinate in a CIE 1931 chromaticity diagram, and x and y in Table 1 and Table 2 respectively represents the x coordinate and the y coordinate. In addition, the thickness of the green photoresist 120g, the first conventional green photoresist, and the second conventional green photoresist in Table 2 are larger that of the Table 1 respectively.

As shown in Table 1 and Table 2, compared to the two conventional green photoresists, the green photoresist 120g has higher light transmittance for the light beam from the standard C light source. In addition, when the thickness of each of the photoresists is increased, the light transmittance of the first conventional green photoresist decreases 5.65% (i.e. (55.2−52.07)/55.2), the light transmittance of the second conventional green photoresist decreases 4.68% (i.e. (56.88−54.22)/56.88), the light transmittance of the green photoresist 120g only decreases 2.2% (i.e. (57.63−56.36)/57.63). Therefore, the display apparatus having high color saturation can be achieved by increasing the thickness of the green photoresist 120g, however, in this instance, the light transmittance of the green photoresist 120g only decreases a little.

As stated above, because GY×Gy is greater than 33 when the green photoresist is tested by a standard C light source and Gy is greater than or equal to 0.6, the light transmittance of the green photoresists is increased. Accordingly, the color filter substrate can achieve high color saturation without greatly decreasing light transmittance. Thus, the display apparatus employs the color filter substrate can achieve high light usage efficiency.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A green photoresist for a color filter substrate, wherein GY×Gy is greater than 33 when the green photoresist is tested by a standard C light source and Gy is greater than or equal to 0.6, a light beam from the standard C light source after passing through the green photoresist corresponds to a y coordinate in a CIE 1931 chromaticity diagram and Gy represents the y coordinate, and GY represents light transmittance of the green photoresist for the light beam from the standard C light source.

2. The green photoresist as claimed in claim 1, wherein the green photoresist comprises at least one kind of green pigments.

3. The green photoresist as claimed in claim 2, wherein the green pigment is composed of halogenated metallophthalocyanine.

4. The green photoresist as claimed in claim 3, wherein halogenated metallophthalocyanine is composed of brominated zinc phthalocyanine.

5. The green photoresist as claimed in claim 2, further comprising at least one kind of yellow pigments.

6. The green photoresist as claimed in claim 5, wherein the yellow pigment comprises C.I. Pigment Yellow 150 and/or C.I. Pigment Yellow 139.

7. The green photoresist as claimed in claim 1, wherein a transmission spectrum of the green photoresist has a relative maximum valve between 520 nm and 580 nm.

8. A color filter substrate, comprising a substrate, a plurality of red photoresists, a plurality of blue photoresists and a plurality of green photoresists, wherein the red photoresists, the blue photoresists and the green photoresists are disposed on the substrate, GY×Gy is greater than 33 when the green photoresist is tested by a standard C light source and Gy is greater than or equal to 0.6, a light beam from the standard C light source after passing through the green photoresist corresponds to a y coordinate in a CIE 1931 chromaticity diagram and Gy represents the y coordinate, and GY represents light transmittance of the green photoresist for the light beam from the standard C light source.

9. The color filter substrate as claimed in claim 8, wherein the green photoresist comprises at least one kind of green pigments.

10. The color filter substrate as claimed in claim 9, wherein, wherein the green pigment is composed of halogenated metallophthalocyanine.

11. The color filter substrate as claimed in claim 10, wherein halogenated metallophthalocyanine is composed of brominated zinc phthalocyanine.

12. The color filter substrate as claimed in claim 9, further comprising at least one kind of yellow pigments.

13. The color filter substrate as claimed in claim 12, wherein the yellow pigment comprises C.I. Pigment Yellow 150 and/or C.I. Pigment Yellow 139.

14. The color filter substrate as claimed in claim 8, wherein a transmission spectrum of the green photoresist has a relative maximum valve between 520 nm and 580 nm.
